(19) United States
(12) Patent Application Publication
(10) Pub. No.: US 2019/0393204 A1
(43) Pub. Date: Dec. 26, 2019

(54) Eliminating defects in stacks

(71) Applicant: Xcelsis Corporation, San Jose, CA (US)

(72) Inventors: Javier A. DELACRUZ, San Jose, CA (US); David Edward FISCH, Pleasanton, CA (US); Pearl Po-Yee CHENG, Los Altos, CA (US)

(73) Assignee: Xcelsis Corporation, San Jose, CA (US)

(21) Appl. No.: 16/014,371

(22) Filed: Jun. 21, 2018

(51) Int. Cl. H01L 25/00; H01L 25/18; H01L 21/66

(52) U.S. Cl. CPC H01L 25/50; H01L 22/22; H01L 25/18

(57) ABSTRACT

Representative implementations of devices and techniques eliminate defects in die-to-die, die-to-wafer, and wafer-to-wafer stacks. In various implementations, the devices and techniques herein disclosed geographically isolate and eliminate one or more regions in a stack that is affected by one or more defects in the stack. Die/wafer stack devices are architected to have redundancy across vertical die columns in control, signaling, and in power supplies.

### FIELD

The following description relates to integrated circuits (“ICs”). More particularly, the following description relates to defects in stacked IC dies and wafers.

### BACKGROUND

Microelectronic elements often comprise a thin slab of a semiconductor material, such as silicon or gallium arsenide, commonly called a semiconductor wafer. A wafer can be formed to include multiple integrated chips or dies on a surface of the wafer and/or partly embedded within the wafer. Dies that are separated from a wafer are commonly provided as individual, prepackaged units. In some package designs, the die is mounted to a substrate or a chip carrier, which is in turn mounted on a circuit panel, such as a printed circuit board (PCB). For example, many dies are provided in packages suitable for surface mounting.

Packaged semiconductor dies can also be provided in “stacked” arrangements, wherein one package is provided, for example, on a circuit board or other carrier, and another package is mounted on top of the first package. These arrangements can allow a number of different dies to be mounted within a single footprint on a circuit board and can further facilitate high-speed operation by providing a short interconnection between the packages. Often, this interconnect distance can be only slightly larger than the thickness of the die itself. For interconnection to be achieved within a stack of die packages, interconnection structures for mechanical and electrical connection may be provided on both sides (e.g., faces) of each die package (except for the topmost package).

Additionally, dies or wafers may be stacked in a three-dimensional arrangement as part of various microelectronic packaging schemes. This can include stacking a layer of one or more dies on a larger base die, stacking multiple dies in a vertical arrangement, and various combinations of both. Dies may also be stacked on wafers or wafers may be stacked on other wafers prior to singulation. The dies or wafers may be bonded in a stacked arrangement using various bonding techniques, including direct bonding, non-adhesive techniques such as a ZiBond® technique or a hybrid DBI® technique, both available from Ziptronix, Inc., a Xperi company (see for example, U.S. Pat. Nos. 6,864,585 and 7,485,968, which are incorporated herein in their entirety).

There can be a variety of challenges to implementing stacked die and wafer arrangements. For example, wafer-to-wafer stacking and bonding can be unattractive if there are sufficient defects that reduce the yield. Defects may be due to particles in the air, impure chemistry, mask defects, and the like. Various defects can result in one or more dies within the stack becoming inoperative for use within the stack.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items.

For this discussion, the devices and systems illustrated in the figures are shown as having a multiplicity of components. Various implementations of devices and/or systems, as described herein, may include fewer components and remain within the scope of the disclosure. Alternately, other implementations of devices and/or systems may include additional components, or various combinations of the described components, and remain within the scope of the disclosure.

FIG. 1A shows an example of a pair of conductive traces on a die, including various examples of potential defects that can occur relative to the pair of conductive traces.

FIG. 1B shows the example of the pair of conductive traces of FIG. 1A, and includes examples of using over-voltages to screen out potential defects, according to an embodiment.

FIG. 2 shows a graph with an example set of failure curves used in manufacturing.

FIG. 3 shows an example of a die-wafer stack with centralized signal paths, according to an embodiment.

FIG. 4 shows an example of a die-wafer stack broken into logical vaults, but with power supplies for the dies tied together throughout the stack, according to an embodiment.

FIG. 5 shows an example die-wafer stack with independent power domains, according to another embodiment.

FIGS. 6A-6D show example scenarios of defect resolution for the die-wafer stack of FIG. 5, according to various embodiments.

FIGS. 7A and 7B show photos of example DRAM stacks, showing possible stack layers, according to an embodiment.

FIGS. 8A-8C show examples of stacked layers of dies, having supplies mixed with signals, according to various embodiments.

FIG. 9 is a flow diagram illustrating an example process for eliminating defects in die-wafer stacks, according to an implementation.

### SUMMARY

In various implementations, a microelectronic system (or device) is arranged to comprise a plurality of semiconductor wafers coupled in a wafer-to-wafer stack, where each wafer includes a plurality of dies. The wafers are aligned such that the plurality of dies of each wafer couple to form a plurality of die stacks (e.g., columns). Each die stack is aligned along an axis generally transverse to a plane of at least one of the wafers. A base die is coupled to the plurality of die stacks, which is configured to provide independent logic, control, and power to each die stack.

In the implementations, defects within the microelectronic system or device are repairable through over-voltage stress events to the plurality of die stacks, which fuse (e.g., melt to eliminate) high-resistance shorts or near-opens. Further, one or more dies of a die stack are recoverable for use after an over-voltage stress event fuses a defect within the die stack that rendered the one or more dies of the die stack inoperable.

In various implementations, the microelectronic system includes at least one active or passive voltage regulator and/or at least one operational amplifier coupled to each die stack. In an example, the voltage regulator and/or operational amplifier are associated to an independent power domain for each die stack. In various embodiments, the voltage regulator and/or operational amplifier are switchable out of circuit during an intentional over-voltage fusing event.

Various implementations and arrangements are discussed with reference to electrical and electronics components and varied carriers. While specific components (i.e., wafers, integrated circuit (IC) chip dies, etc.) are mentioned, this is not intended to be limiting, and is for ease of discussion and illustrative convenience. The techniques and devices discussed with reference to a wafer, die, or the like, are applicable to any type or number of electrical components, circuits (e.g., integrated circuits (IC), mixed circuits, ASICS, memory devices, processors, etc.), groups of components, packaged components, structures (e.g., wafers, panels, boards, PCBs, etc.), and the like, that may be coupled to interface with each other, with external circuits, systems, carriers, and the like. Each of these different components, circuits, groups, packages, structures, and the like, can be generically referred to as a “microelectronic element.”

Implementations are explained in more detail below using a plurality of examples. Although various implementations and examples are discussed here and below, further implementations and examples may be possible by combining the features and elements of individual implementations and examples.

### DETAILED DESCRIPTION

### Overview

Defects in wafer-to-wafer stacking and bonding can result in microelectronic devices or assemblies that are “dead on arrival” or that suffer from “infant mortality,” i.e., becoming inoperative shortly after being put into service due to failures related to the defects. In some cases, the probability of defects in a wafer-to-wafer bonded stack increases exponentially with an increase in the die area. Defects may be due to particles in the air, impure chemistry, mask defects, and the like.

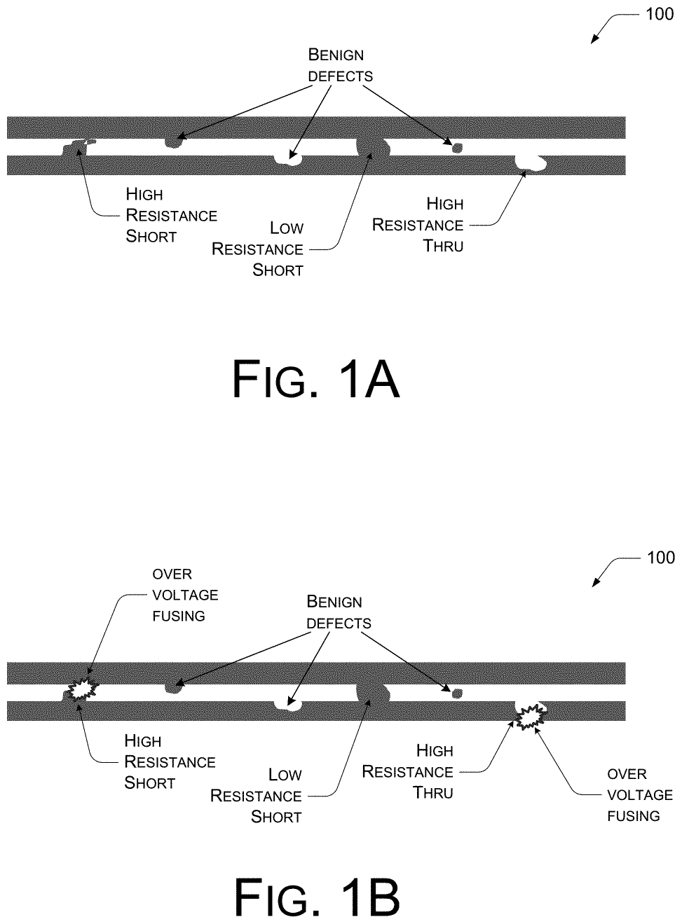

FIG. 1A shows a pair of example conductive traces 100 on a die surface within a die-to-die, die-to-wafer, or wafer-to-wafer stack. The traces 100 may be part of a circuit on the die surface, and may be arranged for transmitting power, signals, data, or the like. In the example illustrated in FIG. 1A, the traces 100 include various examples of potential defects that can occur relative to the pair of conductive traces 100. As shown, various defects can result in high or low resistance shorts between adjacent or nearby traces, high resistance “thrus” on one or more of the traces, as well as benign defects. With one or more such defects on the traces 100, there may be a high likelihood of the associated die being inoperative in its current form, or of the die suffering from infant mortality shortly after being put into service.

In many cases, it is desirable to try to eliminate “walking wounded” defective microelectronics before they are implemented in products and become early “infant mortality” failures. Burn-in procedures, such as illustrated in FIG. 1B, can be performed to screen out the defective dies and wafers, in an attempt to reduce such occurrences. A low-cost burn-in procedure may include subjecting the traces 100 to a brief over-voltage, which can cause some defects to “fuse open” (e.g., to open due to melting of the conductive material of the trace defect). An example burn-in sequence may include: 1) running a test routine on the die or wafer at normal voltage levels and recording pertinent data; 2) re-running the test at 40-60% higher voltage levels (without necessarily recording data) to stress the weak portions of the components (e.g., traces); and 3) re-running the initial test again at normal voltage levels, and recording data to monitor the changes between the first and last tests. The changes between the first and last tests can show dies or portions of dies that are no longer in the tested circuits or loops, for instance. Additionally, the changes can show dies or portions of dies that are now normally operational (e.g., when a high-resistance short is removed).

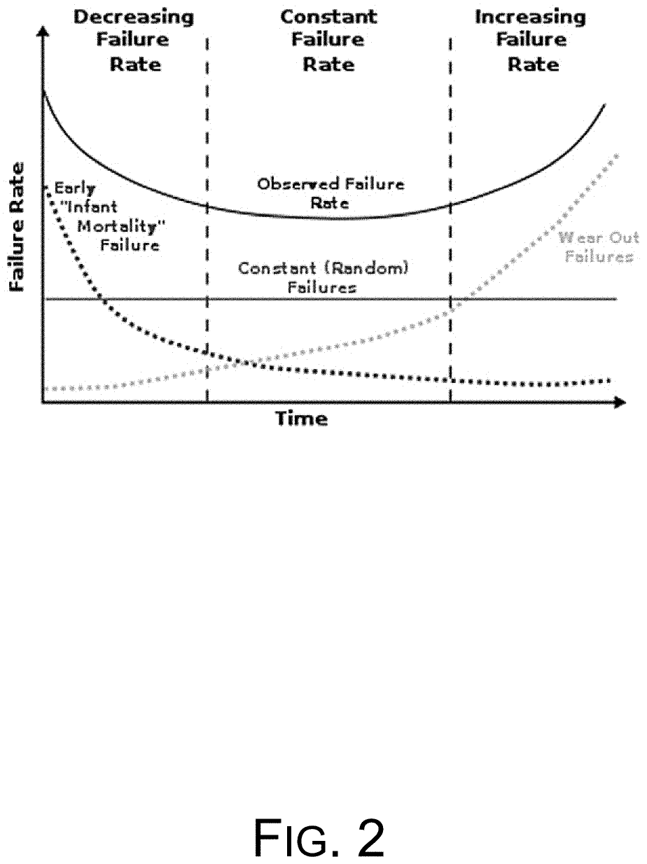

This burn-in sequence can screen out defective dies and wafers, by accelerating failure at a defect, or by eliminating the defect to allow normal operation. For instance, the sequence can reduce the quantity of early “infant mortality” failures represented in the graph of FIG. 2, reducing the failure rate and improving the reliability percentage of all deployed dies and stacked components. However, this routine can also screen out good dies in wafer stacks that are adjacent or near to defective dies. For instance, removing a defective die from a stack can also remove the signal or power paths that lead to dies adjacent to the defective die.

For example, among other applications, wafer and die stacking is implemented for high volume memory, which introduces some testing challenges. When testing a wafer (or wafer stack), the testing often includes connecting to the supply mesh on a die, since there may be few test ports. Performing the wafer test can include driving across the dies which have centralized address/control functions to efficiently access various portions of the dies. In many cases, more comprehensive tests are performed on individual dies than on wafers, however. Instead, wafers may be quality checked at a basic level, and passed for further processing if they pass basic inspections.

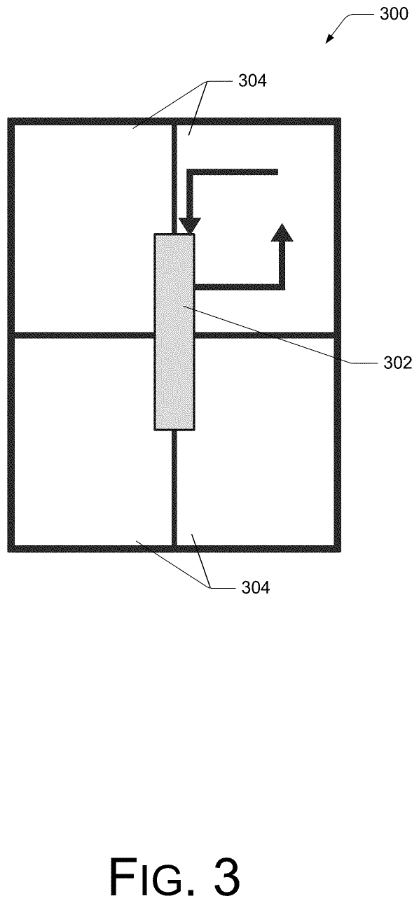

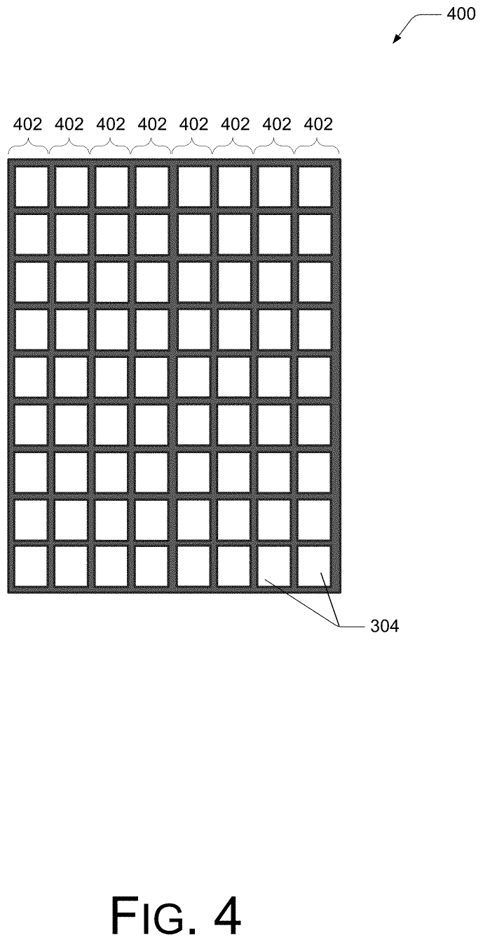

In die-to-wafer stack cases, such as the example of “high bandwidth memory (HBM)” 300 illustrated in FIG. 3, the signaling 302 for the memory may be clustered in the center of a block of dies 304, with minimal other changes from a monolithic DRAM layout. For instance, addressing and control can be located in a base die. To test the stack 300, supplies are shorted throughout the entire stack 300. In another die-to-wafer stack configuration known as a “hybrid memory cube (HMC)” 400, shown in FIG. 4, the stack 400 can be broken into logical “vaults,” comprising vertical stacks 402 of dies 304. The logic and control can be located in a base die capable of addressing each of the vaults 402 individually, but the power supplies are still tied together (common) among the vaults 402.

Example Device Stacks with Independent Banks

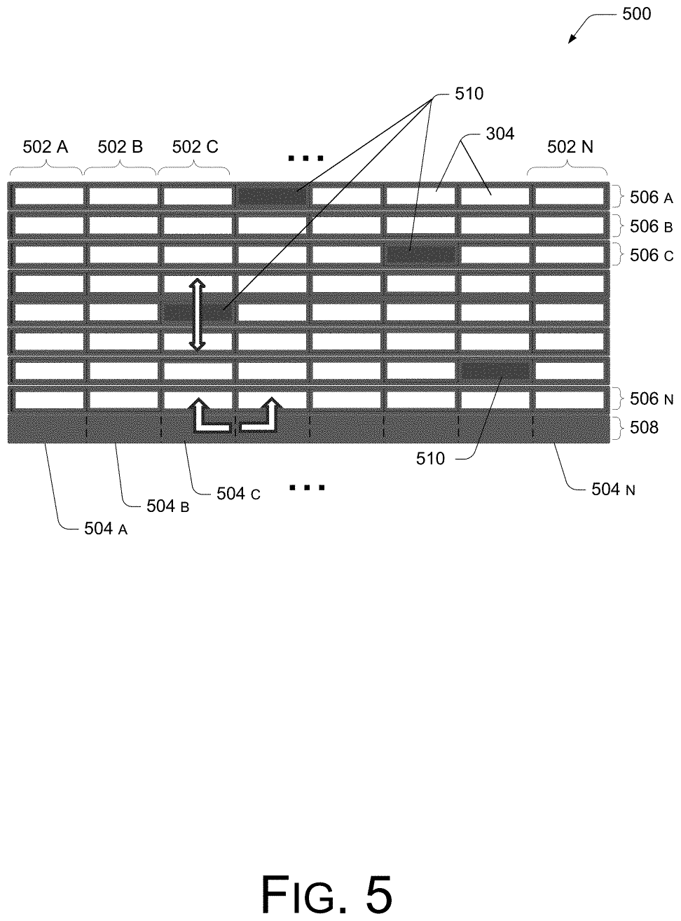

Referring to FIG. 5, representative implementations of devices and techniques are herein disclosed for eliminating defects in die-to-die, die-to-wafer, and wafer-to-wafer stacks. For example, in various implementations, the devices and techniques herein disclosed geographically isolate and eliminate one or more regions in a stack 500 that is affected by one or more defects in the stack 500.

While large defects in a wafer stack 500 can be fatal to the entire stack 500, it is desirable to have the opportunity to repair small defects or to sever the small defects from the wafer stack 500. According to various implementations, techniques and devices are herein disclosed to provide die/wafer stack devices (such as the stack 500, for example) that are architected to have redundancy across vertical die columns 502 in control, signaling, and in power supplies.

For instance, in the implementations, the stack 500 is provided with independent power domains (504a-504n) associated with the die columns (i.e., “banks”) (502a-502n), as well as independent signaling and/or control per column 502 in some embodiments. This architecture prevents one defective domain 504 from affecting another domain 504, and allows for comprehensive testing and mitigation of defects by dies 304 and banks 502.

For example, as shown in FIG. 5, a microelectronic system or device comprises a plurality of semiconductor wafers (506a-506n) coupled in a wafer-to-wafer stack 500, where each wafer 506 includes a plurality of dies 304. The wafers 506 are aligned such that the plurality of dies 304 of each wafer 506 couple to form a plurality of die stacks (i.e., “columns” or “banks”) (502a-502n). As shown in FIG. 5, each die stack 502 is aligned along an axis generally transverse to a plane of at least one of the wafers 506.

A base die/wafer 508 is coupled to the plurality of die stacks 502, and is configured to provide independent logic, control, and power to each die stack 502, via the domains 504. This arrangement allows the base 508 to geographically isolate operational areas of the stack 500 from defective areas, such that defects within the device stack 500 can be repaired or eliminated while preserving as much of the operational portions of the stack 500 as possible. The defects are repaired or eliminated through an over-voltage stress event to one or more of the plurality of die stacks 502, or a portion of a die stack 502, which fuses high-resistance shorts or near-opens in defective dies 510 within the targeted die stacks 502. In an implementation, one or more die stacks 502 (or portions of die stacks 502) can be targeted by switching at the base 508.

For example, in an implementation, the base 508 coupled to each die stack 502 provides signaling/control and power to each individual die 304 or to each die stack 502 of the device stack 500, and can isolate each die stack 502 for testing and mitigation of defects. A fuse event or an anti-fuse event (e.g., switching event) can be triggered for an individual die stack 502 (or a die 304 or set of dies 304) to sever the defective portions of the die stack 502, and to preserve the remainder of the die stack 502 or the device stack 500 for service. In this way, much of the die/wafer stack 500 can be put into use, rather than discarding or re-working the die/wafer stack 500. In various examples, a fuse event can sever defective portions of the die/wafer stack 500, or an anti-fuse event can switch on or off banks 502 of the die/wafer stack 500 to be ignored or applied, respectively.

In various embodiments, the independent power domains (504a-504n) are associated to particular banks 502 (e.g., die stacks, columns) or to portions of banks 502 (sets of dies 304). This arrangement allows greater isolation between the banks 502. In some cases, the multiple power domains 504 may have different voltage outputs to match power requirements of the different banks 502. Power management, addressing, and control are performed from the base die 508 of the die-wafer stack 500. For example, electronic switching for banks 502 or sets of dies 304 is controlled from the base die 508, but may be communicated to switches (not shown) located at any of the die 304 layers of a bank 502. Thus, there may be minimal or no connectivity between regions of the die-wafer stack 500. Logic in the base die 508 manages signal-signal, signal-VDD, and signal-VSS enabling/disabling.

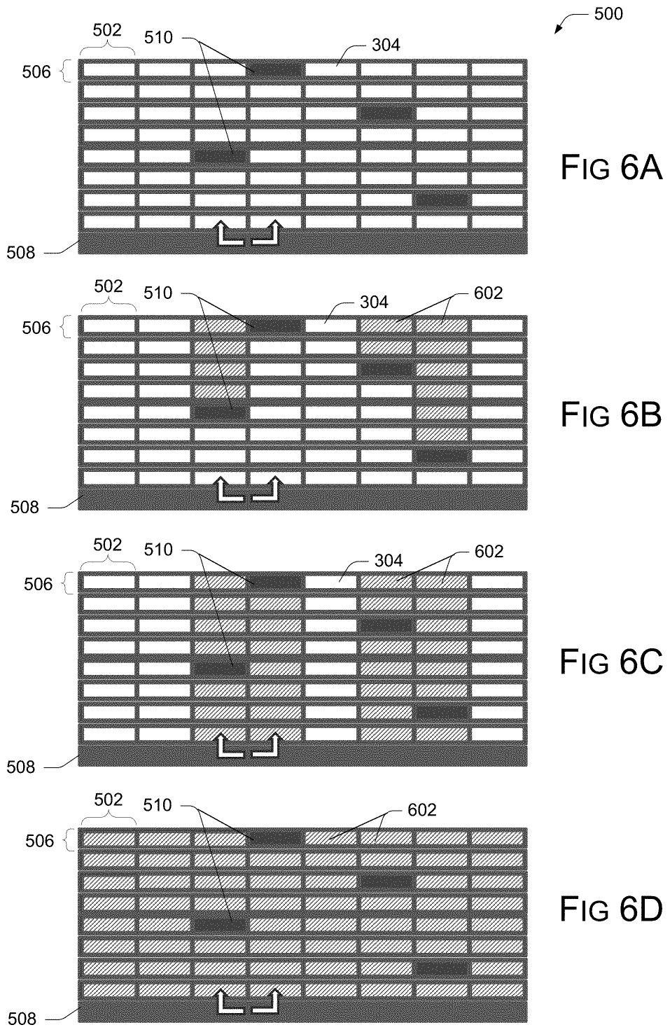

Referring to FIG. 6, in various implementations, a fuse event is used to sever, isolate, or disable as little as possible of the system/device stack 500, depending on the architecture and layout of the system/device stack 500. Depending on the severity of a fusing event, for example, blowing a power supply trace may also affect (e.g., damage) one or more signal interconnections (particularly if the event occurs close to a via). In an implementation, the stack 500 is arranged so that the pass-through vias (e.g., TSVs, etc.) are located at least a predetermined distance from supply traces when possible to reduce additional damage to signal paths during the fusing event. For instance, in one case, as shown in FIG. 6A, no signal interconnections are affected when a power supply short associated to a defective die 510 is fuse-blown, and each of the other dies 304 remains operational. In an alternate embodiment, one or more defective dies 510 can be isolated and removed from the stack 500 by the fusing event (e.g., via switching controlled by the base 508) without affecting the remaining dies 304 of the stack 500.

In another case, as shown in FIG. 6B, some signal interconnections may be affected during a fusing event, but only portions of affected banks 502 are disabled. For example, one or more disabled dies 602 in the associated banks 502 result from the loss of signal or power traces during the fusing event, but other dies 304 remain operational. many of the good sectors of the stack 500 are recovered, rather than lost due to the defects in the stack 500. In an alternate embodiment, switching at the base 508 is used to isolate the defective dies 510 as much as possible, and to minimize the number of disabled dies 602 that will result from the fusing event. In either case, much of the stack 500 is preserved for reliable use.

In a third case, as shown in FIG. 6C, entire banks 502 are disabled due to the fusing event, but the remaining isolated banks 502 with operational dies 304 can still be addressed and used. Finally, in a fourth case, as shown in FIG. 6D, the entire stack 500 may be disabled in the fusing event. However, the fourth case should be rare when the individual banks 502 include independent power and signal domains 504.

In various implementations, the microelectronic system 500 includes at least one operational amplifier (not shown) and/or at least one active or passive voltage regulator (not shown) coupled to each die stack 502. In one example, the operational amplifier and/or voltage regulator are associated to the independent power domain 504 for each bank 502. For instance, the operational amplifier can provide switching or buffering for the dies 304 of the bank 502. Alternately, the switching can be provided by one or more transistors, or the like, per bank 502. Switching components may be disposed at the base 508, within the layers of the bank 502, or disposed at one or more of the dies 304 of the bank 502. The voltage regulator may be passive or active, and can provide a particular voltage supply used by the dies 304 of the associated bank 502. The voltage regulators can be disabled during the over-voltage fusing event to more effectively drive the peak voltage burst of the event. In various embodiments, the voltage regulator(s) may also be disposed at the base 508, within the layers of the bank 502, or disposed at one or more of the dies 304 of the bank 502.

In further embodiments, the disclosed microelectronic devices 500 may have one or more additional components within the base 508 or located in the layers of dies 304. For example, a device 500 may include: switched power supplies at the base die 508; fusible power traces per die 304; single or dual power supplies connected at the base die 508 (e.g., one supply at a top level and one at the base die 508, etc.); different power supplies (VDD, VSS) for different banks 502; a capability for testing the current at each bank 502; isolation between banks 502 implemented with physical or electrical switching (e.g., power gates) to isolate banks 502 for testing or fusing; electrical isolation components located on one of the upper level dies 304 that are controlled by logic at the base die 508; chip select components/logic to select a single die layer of a bank 502 (using vias, etc.); a capability for wafer 506 testing prior to DBI or other direct bond techniques; package level fuse control; testing and fuse blowing through an interposer or other package layer; and so forth.

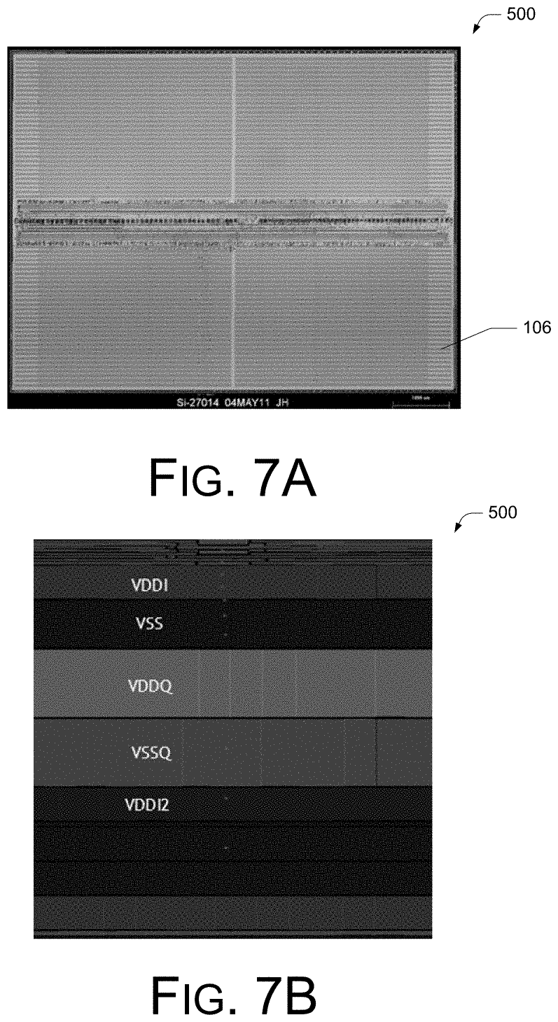

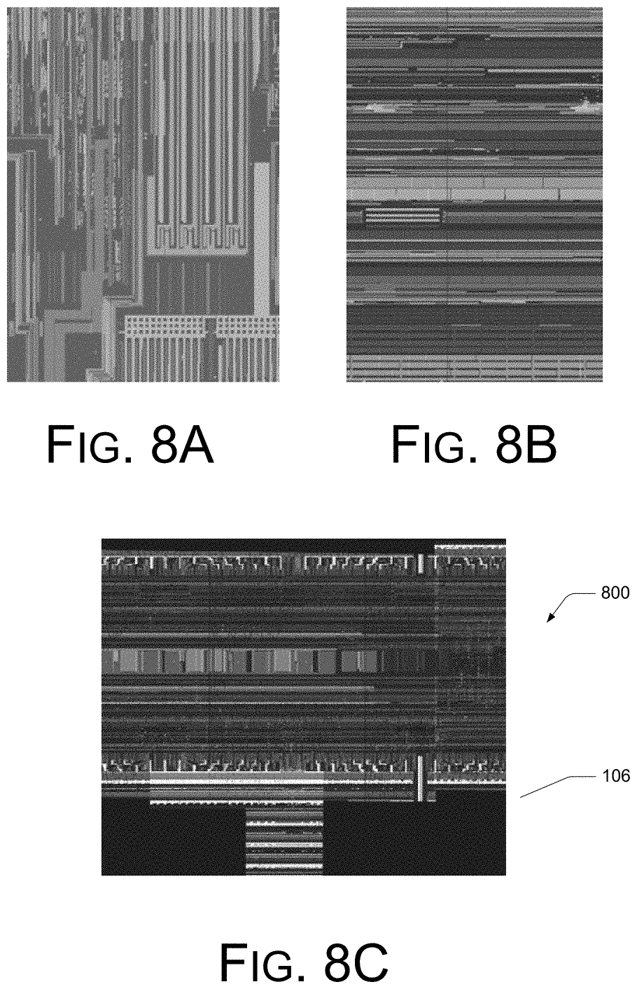

FIGS. 7A and 7B show photos of example DRAM stacks 500, showing possible stack layers, according to an embodiment. In the examples shown, mainly supplies are located on the top layer(s). FIGS. 8A-8C show examples of stacked layers of dies 304, having supplies mixed with signals, according to various embodiments.

The techniques, components, and devices described herein with respect to the device/system stack 500 are not limited to the illustrations in FIGS. 1-8, and may be applied to other designs, types, arrangements, and constructions including with other electrical components without departing from the scope of the disclosure. In some cases, additional or alternative components, techniques, sequences, or processes may be used to implement the techniques described herein. Further, the components and/or techniques may be arranged and/or combined in various combinations, while resulting in similar or approximately identical results.

Unless otherwise specified, additional or alternative components to those specifically mentioned may be used to implement the techniques described herein. In various implementations, a device/system stack 500 may be a stand-alone unit, or it may be a portion of a system, component, structure, or the like.

### Representative Process

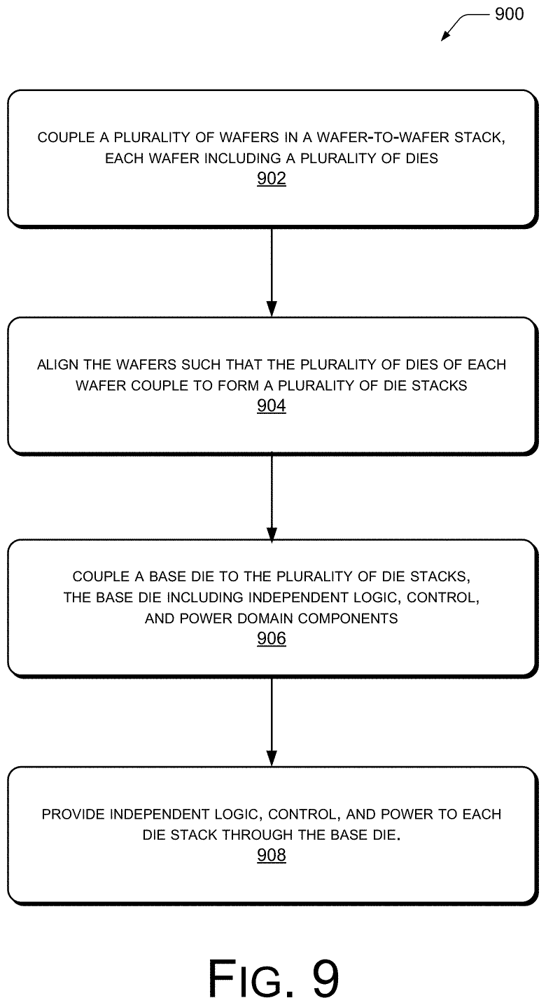

FIG. 9 illustrates a representative process 900 for implementing techniques and/or devices relative to eliminating defects in die/wafer stacks (such as stack 500, for example). The process 900 includes providing stacked devices and systems that are architected to have redundancy across vertical die columns in control, signaling, and in power supplies. The example process 900 is described with reference to FIGS. 1A-9.

The order in which the process is described is not intended to be construed as a limitation, and any number of the described process blocks can be combined in any order to implement the process, or alternate processes. Additionally, individual blocks may be deleted from the process without departing from the spirit and scope of the subject matter described herein. Furthermore, the process can be implemented in any suitable hardware, software, firmware, or a combination thereof, without departing from the scope of the subject matter described herein.

At block 902, the process includes coupling a plurality of wafers (such as wafers 506, for example) in a wafer-to-wafer stack, wherein each wafer includes a plurality of dies (such as dies 304, for example).

At block 904, the process includes aligning the wafers such that the plurality of dies of each wafer couple to form a plurality of die stacks (such as die stacks 502, for example).

At block 906, the process includes coupling a base die (such as base 508, for example) to the plurality of die stacks. The base die includes independent logic, control, and power domain components.

At block 908, the process includes providing independent logic, control, and power to each die stack through the base die. For example, in one embodiment, the process includes providing an independent power supply to each die stack via an active or passive voltage regulator associated to the die stack.

In an implementation, the process includes repairing defects within one or more die stacks through over-voltage stress events applied to one or more of the plurality of die stacks. The over-voltage stress events are arranged to fuse open high-resistance shorts or near-opens within the one or more die stacks. In an embodiment, the process includes isolating dies having defects within the one or more die stacks and functionally severing the dies having defects from the one or more die stacks via the over-voltage stress events, without rendering inoperable remaining dies within the one or more die stacks.

In an implementation, the process includes isolating dies of one or more other die stacks from the over-voltage stress events applied to the one or more of the die stacks through switching controlled by the base die. For example, in some embodiments, the process includes providing the switching via one or more operational amplifiers disposed at the base die or within the one or more of the die stacks. In alternate embodiments, the switching is provided by one or more transistors, or the like.

In an implementation, the process includes recovering one or more dies of a defective die stack for use by applying an over-voltage stress event to the defective die stack, the over-voltage stress event fusing open a defect within the defective die stack that rendered the one or more dies of the defective die stack inoperable.

In alternate implementations, other techniques may be included in the process in various combinations, and remain within the scope of the disclosure.

### CONCLUSION

Although the implementations of the disclosure have been described in language specific to structural features and/or methodological acts, it is to be understood that the implementations are not necessarily limited to the specific features or acts described. Rather, the specific features and acts are disclosed as representative forms of implementing example devices and techniques.

What is claimed is:

1. A microelectronic system, comprising:
a plurality of semiconductor wafers coupled in a wafer-to-wafer stack, each wafer including a plurality of dies, the wafers aligned such that the plurality of dies of each wafer couple to form a plurality of die stacks, each die stack aligned along an axis generally transverse to a plane of at least one of the wafers; and
a base die coupled to the plurality of die stacks, the base die configured to provide independent logic, control, and power to each die stack, such that defects within the system are repairable through over-voltage stress events to the plurality of die stacks, which fuse open high-resistance shorts or near-opens.

2. The microelectronic system of claim 1, further comprising a plurality of independent power domains, each independent power domain arranged to provide an independent voltage supply to an associated die stack.

3. The microelectronic system of claim 1, further comprising at least one active or passive voltage regulator and/or at least one operational amplifier coupled to each die stack.

4. The microelectronic system of claim 3, wherein the at least one active or passive voltage regulator is switchable out of circuit during an intentional over-voltage fusing event.

5. The microelectronic system of claim 1, further comprising one or more switching components controlled at the base die and arranged to isolate signal, control, or supply paths of one or more regions of the wafer-to-wafer stack from other regions of the wafer-to-wafer stack.

6. The microelectronic system of claim 1, wherein one or more dies in a die stack are recoverable for use after an over-voltage stress event fuses open a defect within the die stack that renders the one or more dies of the die stack inoperable.

7. The microelectronic system of claim 1, wherein the base die is arranged to isolate and functionally sever one or more regions of the wafer-to-wafer stack that is affected by a defect in the wafer-to-wafer stack, and to recover one or more other regions of the wafer-to-wafer stack that are adjacent to the defect in the wafer-to-wafer stack.

8. A microelectronic system, comprising:
a plurality of semiconductor wafers coupled in a wafer-to-wafer stack, each wafer including a plurality of dies, the wafers aligned such that the plurality of dies of each wafer couple to form a plurality of die stacks;
a base die coupled to the plurality of die stacks, the base die including independent logic, control, and power circuitry for each die stack; and
a plurality of power domains coupled to corresponding die stacks of the plurality of die stacks, the power domains arranged to provide an independent power supply to each of the die stacks.

9. The microelectronic system of claim 8, further comprising logic in the base die arranged to control enabling and disabling of signal-to-signal, signal-to-supply, and supply-to-supply circuit paths within the die stacks.

10. The microelectronic system of claim 8, further comprising at least one active or passive voltage regulator and/or at least one operational amplifier associated to an independent power domain for each die stack.

11. The microelectronic system of claim 8, further comprising one or more pass-through vias arranged to route signal paths between adjacent dies of the die stacks, the one or more vias disposed at least a predetermined distance from any power supply path.

12. The microelectronic system of claim 8, wherein the base die is arranged to isolate and functionally sever one or more regions of the wafer-to-wafer stack from other regions of the wafer-to-wafer stack, such that defects within one or more dies of the plurality of die stacks are isolated through over-voltage stress events to the plurality of die stacks, without rendering remaining dies of the plurality of die stacks inoperative.

13. The microelectronic system of claim 8, wherein the base die is arranged to use the independent logic, control, and power circuitry to recover operative regions of the wafer-to-wafer stack that would otherwise be rendered inoperable due to the proximity of the regions to a defect within the wafer-to-wafer stack.

14. A method, comprising:
coupling a plurality of wafers in a wafer-to-wafer stack, each wafer including a plurality of dies;
aligning the wafers such that the plurality of dies of each wafer couple to form a plurality of die stacks;
coupling a base die to the plurality of die stacks, the base die including independent logic, control, and power domain components; and
providing independent logic, control, and power to each die stack through the base die.

15. The method of claim 14, further comprising repairing defects within one or more die stacks through over-voltage stress events applied to one or more of the plurality of die stacks, the over-voltage stress events arranged to fuse open high-resistance shorts or near-opens within the one or more of the die stacks.

16. The method of claim 15, further comprising isolating dies having defects within the one or more die stacks and functionally severing the dies having defects from the one or more die stacks via the over-voltage stress events, without rendering inoperable remaining dies within the one or more die stacks.

17. The method of claim 15, further comprising isolating dies of one or more other die stacks from the over-voltage stress events applied to the one or more of the die stacks through switching controlled by the base die.

18. The method of claim 17, further comprising providing the switching via one or more operational amplifiers disposed at the base die or within the one or more of the die stacks.

19. The method of claim 14, further comprising recovering one or more dies of a defective die stack for use by applying an over-voltage stress event to the defective die stack, the over-voltage stress event fusing open a defect within the defective die stack that rendered the one or more dies of the defective die stack inoperable.

20. The method of claim 14, further comprising providing an independent power supply to each die stack via an active or passive voltage regulator associated to the die stack.
